(19) United States
(12) Patent Application Publication
(10) Pub. No.: US 2016/0189954 A1
(43) Pub. Date: Jun. 30, 2016

(54) METHODS OF PERFORMING SEMICONDUCTOR GROWTH USING REUSABLE CARRIER SUBSTRATES AND RELATED CARRIER SUBSTRATES

(71) Applicant: Cree, Inc., Durham, NC (US)

(72) Inventors: Hua-Shuang Kong, Cary, NC (US); John A. Edmond, Durham, NC (US); Matthew Donofrio, Raleigh, NC (US); Michael J. Bergmann, Raleigh, NC (US); David B. Slater, JR., Durham, NC (US)

(21) Appl. No.: 14/587,024

(22) Filed: Dec. 31, 2014

(51) Int. Cl. H01L 21/02; H01L 21/683; H01L 21/78

(52) U.S. Cl. CPC H01L 21/02529; H01L 21/02378; H01L 21/02422; H01L 21/0262; H01L 21/78; H01L 21/6835; H01L 2221/68345; H01L 2221/68381; H01L 2221/68327

(57) ABSTRACT

Semiconductor devices are fabricated by providing a growth substrate having a thickness within a preselected range and then bonding a lower surface of the growth substrate to an upper surface of the carrier substrate to form a composite substrate. One or more semiconductor growth processes are performed at one or more growth temperatures of at least 500° C. to form one or more semiconductor layers on an upper surface of the composite substrate. The growth substrate is separated from the carrier substrate after the one or more semiconductor growth processes are completed so that the carrier substrate may be reused with a second growth substrate.

### FIELD OF THE INVENTION

The present invention relates to semiconductor fabrication techniques and, more particularly, to methods of forming semiconductor layers on a growth substrate.

### BACKGROUND

Semiconductor devices are typically fabricated using so-called epitaxial growth techniques, whereby thin semiconductor “epitaxial” layers are formed on an underlying crystalline substrate. The crystalline substrate may comprise, for example, a semiconductor substrate (e.g., a silicon substrate), a non-semiconductor substrate such as, for example, a glass or sapphire substrate, or a combination of the two (e.g., a silicon-on-insulator substrate). Typically, the crystalline substrate is substantially thicker than the epitaxial layers that are grown thereon. The epitaxial layers may be grown on the substrate using, for example, vapor-phase, liquid-phase or solid-phase epitaxy techniques. Many commercial semiconductor fabrication operations use vapor-phase epitaxial growth techniques.

Vapor-phase semiconductor epitaxial growth processes are high temperature growth processes in which the semiconductor epitaxial layers are grown on the crystalline substrate in a high temperature growth reactor. The crystalline substrate is placed in the reactor and the reactor is heated to a high temperature (e.g., greater than 500° C.). Source gases (e.g., ammonia, tri-methyl gallium, etc.) that include the constituent elements of the epitaxial layers that are to be grown (e.g., gallium, nitrogen, etc.) are allowed to flow into the reactor and are broken down into their constituent elements at high temperatures. The constituent elements may reform into crystalline structures on an exposed upper surface of a crystalline growth substrate that is mounted in the growth reactor. For example, gallium atoms from a tri-methyl gallium source gas and nitrogen atoms from an ammonia source gas may deposit onto a sapphire substrate to grow a gallium nitride layer on the sapphire substrate. Non-semiconductor layers, such as metal layers, insulating layers (e.g., silicon oxide, silicon nitride, etc.) and the like may also be deposited on the substrate either in the growth reactor or during subsequent processing.

### SUMMARY

Pursuant to embodiments of the present invention, methods of fabricating semiconductor devices are provided in which a growth substrate is provided that has a thickness within a preselected range. A lower surface of the growth substrate is bonded to an upper surface of the carrier substrate to form a composite substrate. A semiconductor growth process is performed at a growth temperature of at least 500° C. to form a semiconductor layer on an upper surface of the growth substrate. The growth substrate may be separated from the carrier substrate after the one or more semiconductor growth processes are completed.

In some embodiments, after the above describe method is performed a second growth substrate may be provided that has a thickness within a preselected range. A lower surface of the second growth substrate may be bonded to the upper surface of the carrier substrate to provide a second composite substrate. A second semiconductor growth process may then be performed on the second composite substrate at a temperature of at least 500° C. to form a second semiconductor layer on an upper surface of the second growth substrate. The second growth substrate may be separated from the carrier substrate after the semiconductor growth process is completed.

In some embodiments, the upper surface of the carrier substrate may be patterned prior to bonding the lower surface of the growth substrate to the carrier substrate. In such embodiments, the upper surface of the carrier substrate may be patterned to have a recessed upper surface, and a plurality of protrusions may extend upwardly from the recessed upper surface, and a plurality of recessed regions may be provided between the protrusions. The upper surfaces of the protrusions may define a bonding surface that contacts the lower surface of the growth substrate when the lower surface of the growth substrate is bonded to the upper surface of the carrier substrate, and this bonding surface may have a surface area that is less than 50% of the surface area of the lower surface of the growth substrate. recessed regions may define a non-contact region where the carrier substrate does not contact the lower surface of the growth substrate, and in a central region of the upper surface of the carrier substrate the ratio of the surface area of the bonding surface to the surface area of the non-contact region is less than the ratio of the surface area of the bonding surface to the surface area of the non-contact region in a peripheral region of the upper surface of the carrier substrate that surrounds the central region.

In some embodiments, a thickness of the first growth substrate may be selected based on a desired substrate thickness for the semiconductor device. The growth substrate may be diced after it is separated from the carrier substrate without any thinning of the growth substrate.

In some embodiments, the first growth substrate may be a first silicon carbide growth substrate and the carrier substrate may be a silicon carbide carrier substrate. In such embodiments, the first silicon carbide growth substrate may be bonded to the upper surface of the silicon carbide carrier substrate using at least one of carbon, silicon oxide, and/or silicon. In other embodiments, the first growth substrate may be a first sapphire growth substrate and the carrier substrate may be a sapphire carrier substrate or an alumina carrier substrate.

In some embodiments, a thickness of the carrier substrate may be at least three times a thickness of the first growth substrate and at least three times a thickness of the second growth substrate. The semiconductor growth process may be an epitaxial growth process, and at the epitaxial layer may have a different coefficient of thermal expansion than does the growth substrate.

Pursuant to further embodiments of the present invention, methods of fabricating semiconductor devices are provided in which a plurality of semiconductor layers are epitaxially grown on a composite substrate that includes a growth substrate having a lower surface that is bonded to an upper surface of a carrier substrate. The upper surface of the carrier substrate includes recesses therein that define voids at the interface between the carrier substrate and the growth substrate. The growth substrate is separated from the carrier substrate by filling the voids with a fluid that is subsequently used to generate an expanding force that separates the growth substrate from the carrier substrate. The expanding force may comprise, for example, a force due to hydraulic pressure and/or a force resulting from a phase change from a liquid fluid to a gaseous fluid.

In some embodiments, the fluid may be a fluid that is inserted into the voids as a liquid and the expanding force may be generated by changing the phase of the liquid to create increased pressure. For example, liquid water may be converted to a gas phase (steam) or to a solid phase (ice) to create the increased pressure. The water may be inserted into the voids, for example, by submerging the composite substrate in water.

Pursuant to still further embodiments of the present invention, composite substrates are provided that include a first substrate that has a first major surface that is patterned to include at least one protrusion that extends away from the first major surface and a second major surface that is opposite the first major surface. These composite substrates also have a second substrate that has first and second opposed major surfaces, and the second major surface of the second substrate is mated with the first major surface of the first substrate. A plurality of semiconductor epitaxial layers are formed on either the second major surface of the first substrate or the first major surface of the second substrate. A distal end of the at least one protrusion is joined to the second major surface of the second substrate.

In some embodiments, the first substrate may be a carrier substrate and the second substrate may be a growth substrate. In other embodiments, the first substrate may be a growth substrate and the second substrate may be a carrier substrate. The composite substrate may also include one or more bonding materials that are disposed between the first substrate and the second substrate that bond the first substrate to the second substrate. The at least one protrusion may be a plurality of protrusions which each have a distal end having a flat surface that is parallel to the second major surface of the first substrate, where the distal end of each protrusion may be bonded to the second major surface of the second substrate.

In some embodiments, a combined surface area of the flat surfaces of the plurality of protrusions may be less than 50% of the surface area of the second major surface of the first substrate. The second substrate may have a diameter that exceeds a thickness of the second substrate by at least a factor of 500. The first substrate may have a thickness that exceeds a thickness of the second substrate by at least a factor of two. A first of the semiconductor epitaxial layers may have a coefficient of thermal expansion that is the same as the coefficient of thermal expansion of the substrate or may have a coefficient of thermal expansion that differs from a coefficient of thermal expansion of the second substrate by, for example, a factor of as much as six (or even higher in some cases).

### BRIEF DESCRIPTION OF THE DRAWINGS

FIGS. 1A-1C are a perspective view, a side view and an exploded perspective view, respectively, of a composite substrate according to certain embodiments of the present invention.

FIG. 1D is a side view of the composite substrate of FIGS. 1A-1C with a plurality of semiconductor epitaxial layers formed thereon.

FIGS. 2A and 2B are an enlarged plan view and a partial cross-sectional view of a carrier substrate according to embodiments of the present invention that has a patterned upper surface.

FIG. 3 is a flow chart illustrating a method of fabricating a semiconductor device according to certain embodiments of the present invention.

FIGS. 4A-4C are schematic side-view diagrams illustrating a method of separating a growth substrate from a carrier substrate according to embodiments of the present invention.

FIG. 5 is a schematic diagram illustrating a method of separating a growth substrate from a carrier substrate according to further embodiments of the present invention.

FIGS. 6A and 6b are schematic side-view diagrams illustrating a method of separating a growth substrate from a carrier substrate according to still further embodiments of the present invention.

FIGS. 7A-7G are schematic plan views of patterned carrier substrates according to certain embodiments of the present invention.

FIGS. 8A and 8B are a schematic plan view and a schematic side view, respectively, of a carrier substrate having a roughened surface according to embodiments of the present invention.

FIGS. 9A and 9B are a perspective view and plan view, respectively, of carrier substrates having perforations according to embodiments of the present invention.

FIG. 10 is a flow chart illustrating a method of fabricating a semiconductor device according to further embodiments of the present invention.

FIG. 11 is a side view of a composite substrate according to still further embodiments of the present invention.

### DETAILED DESCRIPTION

As the diameter of the substrates (e.g., wafers) that are used in semiconductor epitaxial growth processes increases, there may be an increased tendency for the substrate to warp (i.e., bow, bend or otherwise deform) during the high temperature semiconductor growth processes and/or the cool down therefrom. This tendency is particularly strong in situations where the substrate comprises a first material and the epitaxial layers comprise one or more second materials that have different thermal properties (e.g., different coefficients of thermal expansion) than the first material, as the differences in the thermal properties of the materials may generate stress in at least one of the two materials.

By way of example, a thin semiconductor layer having a first thermal expansion coefficient may be grown at high temperature on a thick substrate that has a second thermal expansion coefficient that is greater than the first thermal expansion coefficient. When the substrate with the epitaxial layer grown thereon is cooled, both the substrate and the epitaxial layer will tend to shrink in size, but the substrate will “want” to shrink more than the epitaxial layer because it has a higher coefficient of thermal expansion. If the epitaxial layer is strongly adhered to the substrate, as is typically the case, then both the substrate and the epitaxial layer must maintain the same lateral size. Since the substrate typically is far thicker than the epitaxial layer, the epitaxial layer is forced to shrink more during cooling than it would were it not on the substrate. As this occurs, a significant strain can be produced in the epitaxial layer and/or the substrate.

If the strain that builds up in the epitaxial layer is too great, then a number of things can happen. In some cases, where adhesion between the two materials is very good, the epitaxial layer may buckle and/or crack in order to relieve the strain. In other cases where the adhesion between the materials is not as strong, the epitaxial layer may partially detach from the substrate to relieve the strain. In still other cases, the strain may warp the underlying substrate if the underlying substrate is not sufficiently thick to resist such warpage.

In many semiconductor growth systems, the substrate may be the same material as the epitaxial layers that are grown at high temperature on the substrate in the growth reactor. However, this is not always the case. For example, many Group III-nitride semiconductor materials such as gallium nitride-based semiconductor materials are typically grown via vapor-phase epitaxy techniques on either silicon carbide or sapphire (Al₂O₃) substrates. The coefficients of thermal expansion for gallium nitride and silicon carbide are not well-matched, and the coefficients of thermal expansion for gallium nitride and sapphire are even farther apart. Accordingly, if the growth substrate is too thin, then the strain that builds up in the gallium nitride-based layer due to the tendency of the epitaxial layer and the growth substrate to shrink by different amounts during cooling may be sufficient to warp the underlying substrate. Such warpage may cause substantial processing difficulties such as, for example, difficulties in achieving uniform epitaxial growth across a substrate, which may be very important for achieving high production yields. To reduce the amount of warpage that occurs, complicated changes may be made to the growth apparatus, such as designing substrate carriers to conform to the warping of the substrate and/or forming the growth substrate may be formed to an increased thickness to reduce the warpage by confining most of the strain in the epitaxially grown layers.

Unfortunately, a number of commonly-used semiconductor growth substrates such as sapphire and silicon carbide may be relatively expensive, as are various other growth substrate materials such as, for example, aluminum nitride, gallium nitride and diamond substrates. If these growth substrates must be made thick to reduce warping during cool-down, then this results in a corresponding increase in material costs, as all else being equal, thicker growth substrates are generally more expensive than thin substrates. Worse yet, in many applications, the substrate of the finished semiconductor device may need to be quite thin in order to, for example, reduce the size of the finished chip. In such applications, it is often necessary to perform backend substrate thinning operations where all or part of the growth substrate is removed via, for example, a grinding operation. Such thinning operations are often labor-intensive, require expensive consumable materials (e.g., a diamond slurry, grinding wheels) and capital equipment such as lapping or grinding tools and hence can be expensive to perform. Thus, the use of thicker growth substrates also increases production costs.

As an example, typical thicknesses for 2″, 100 mm (about 4″) and 150 mm (about 6″) sapphire substrates that are used as growth substrates for gallium nitride based semiconductor devices are 0.43 mm, 0.65 mm and 1.3 mm, respectively. A typical thickness for the end semiconductor device, however, may only be about 0.15 mm in many applications. Thus, approximately 65-85% of the growth substrate may be removed by back-end substrate thinning operations. Moreover, as larger diameter substrates are used (which in general can reduce production costs), the warping problem increases (requiring even thicker growth substrates), as does the cost of thinning the substrates post-growth.

Pursuant to embodiments of the present invention, methods of fabricating semiconductor devices are provided in which a relatively thin growth substrate is bonded to a thicker carrier substrate, and semiconductor epitaxial layers are then formed on an upper surface of the growth substrate. After the epitaxial growth is completed (and either before or after other post-growth processing steps such as metallization, passivation, etc.), the carrier substrate may be separated from the growth substrate via a separate operation. The carrier substrate may then be reused with a second growth substrate to epitaxially grow semiconductor layers on the second growth substrate. Thus, pursuant to the techniques according to embodiments of the present invention, a reusable carrier substrate may be used to grow epitaxial layers on thin growth substrates. This approach may significantly reduce the material costs for growth substrates as each growth substrate may be thinner than normal, and may also significantly reduce backend processing costs, as significantly less substrate thinning may be required. In fact, in some embodiments, the growth substrate may have a thickness that is appropriate for the final product in order to remove any need to perform backend substrate thinning.

In some embodiments, an upper surface of the carrier substrate may be patterned to facilitate separating the growth substrates from the carrier substrate. For example, grooves or other recesses may be formed in the upper surface of the carrier substrate so that the carrier substrate has a recessed upper surface with a plurality of protrusions extending upwardly therefrom. The recesses may separate the protrusions from one another. By patterning the upper surface of the carrier substrate in this fashion, the surface area of the upper surface of the carrier substrate that contacts the lower surface of the growth substrate may be reduced. This reduced amount of contact area may, in turn, reduce the strength of the bond between the two substrates. While it may be desirable that the two substrates bond together sufficiently so that the bonded substrates will appear as a single substrate during the high temperature epitaxial growth processes (in order to provide high production yields), it may also be desirable to ensure that the bonding operation can be consistently reversed without damage to the semiconductor devices that are formed on the growth substrate. The sizes of the recesses and the protrusions may be adjusted so that the strength of the bonds holding the substrates together may meet these criteria. The grooves or other recesses may also advantageously provide paths for injecting fluids and/or etchants in between the two substrates that may be used to degrade or break the bonds between the substrates, as will be discussed in greater detail below.

Example embodiments of the present invention will now be described with reference to the attached drawings.

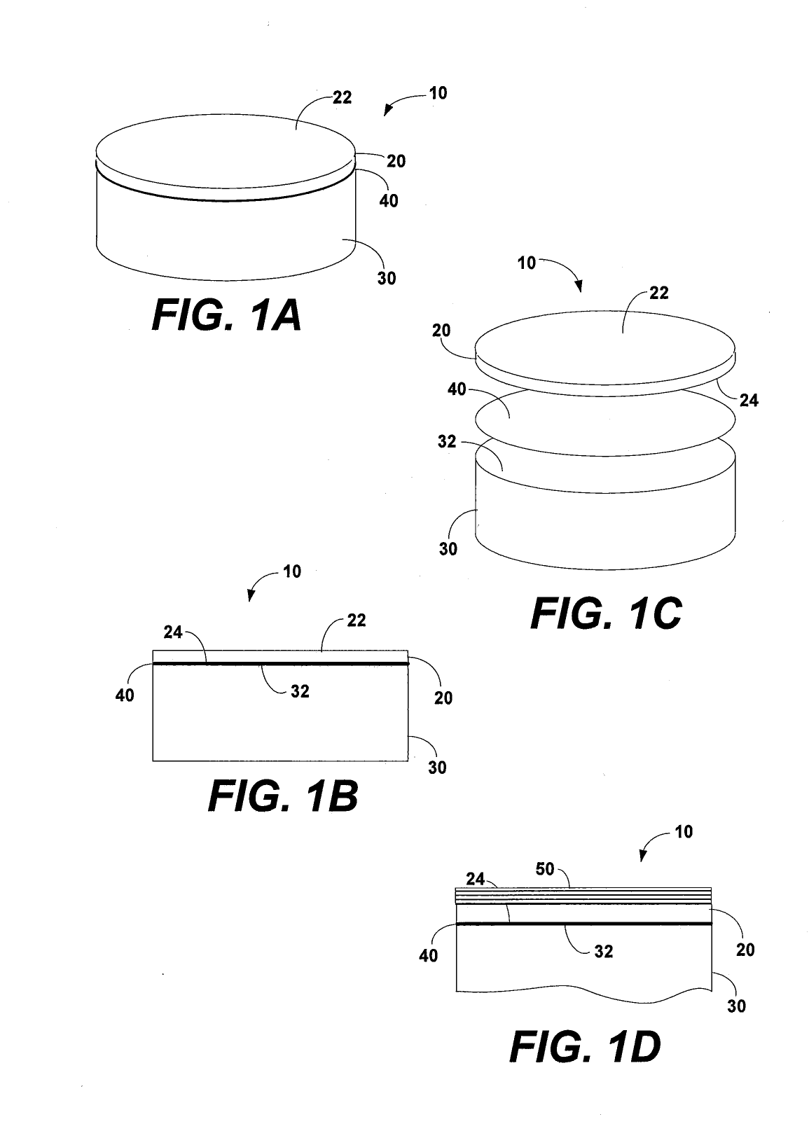

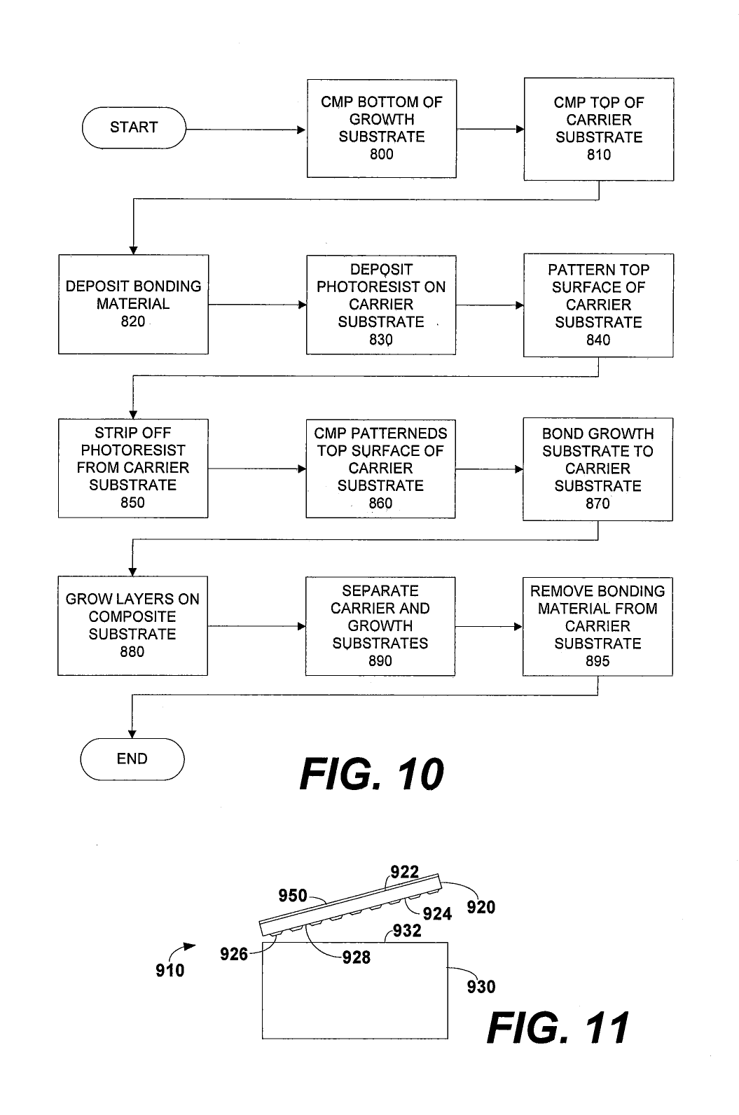

FIGS. 1A-1C, are a perspective view, a side view and an exploded perspective view, respectively, of a composite substrate 10 according to certain embodiments of the present invention. FIG. 10 is a side view of the composite substrate 10 of FIGS. 1A-1C with a plurality of semiconductor epitaxial layers formed thereon.

As shown in FIGS. 1A-1C, the composite substrate 10 comprises a growth substrate 20 and a carrier substrate 30. The growth substrate 20 is bonded to the carrier substrate 30 via a bonding material 40. The growth substrate 20 has an upper surface 22 and a lower surface 24. The growth substrate 20 may comprise a material that is suitable for forming semiconductor devices thereon via, for example, epitaxial growth processes. In some embodiments, the growth substrate 20 may comprise a sapphire (Al₂O₃) substrate, a silicon carbide substrate, an aluminum nitride substrate, a gallium nitride substrate, a silicon substrate or a diamond substrate. When silicon carbide substrates are used, the substrate may be a monocrystalline or a polycrystalline silicon carbide substrate, and may be formed by, for example, chemical vapor deposition or sintering. It will be appreciated, however, that numerous other growth substrates may be used (e.g., silicon-germanium, II-VI compound semiconductor substrates, other III-V compound semiconductor substrates, etc.). The growth substrate 20 may comprise a material that is suitable as a surface for crystal growth. In some embodiments, the growth substrate 20 may comprise, for example, a thin wafer that is cut from a boule of material. Typically such a wafer will have first and second generally planar opposed major surfaces. (which form the upper surface 22 and the lower surface 24). A distance between these major surfaces (i.e., the thickness of the wafer) is typically much smaller than the diameter of the wafer (e.g., a thickness that is 100 times smaller than the diameter of the wafer).

The carrier substrate has an upper surface 32 that is bonded to the lower surface 24 of the growth substrate 20. The lower surface 24 of the growth substrate 20 may be bonded directly to the upper surface 32 of the carrier substrate 30, or intervening material(s) such as a bonding material 40 may be interposed between the growth substrate 20 and the carrier substrate 30. Although it need not be, the carrier substrate 30 will typically be thicker than the growth substrate 20. In some cases the carrier substrate 30 may be substantially thicker than the growth substrate 20 (e.g., three times, five times, ten times or even more). The carrier substrate 30 may comprise, for example, a sapphire (Al₂O₃) substrate, a monocrystalline silicon carbide substrate, a polycrystalline silicon carbide substrate (formed by, for example, chemical vapor deposition or sintering), an aluminum nitride substrate, a gallium nitride substrate, a silicon substrate, a diamond substrate, a silicon-germanium substrate or various other II-VI or III-V semiconductor substrates. The carrier substrate 30 may be the same material as the growth substrate 20. For example, if the growth substrate 20 is a sapphire growth substrate, the carrier substrate 30 may be a sapphire carrier substrate 32. However, it will also be appreciated that in some embodiments the carrier substrate 30 and the growth substrate 20 may be formed of different materials. When this is the case, preferably the carrier substrate 30 and the growth substrate 20 will have coefficients of thermal expansion that are relatively closely matched. For example, in one specific embodiment, the growth substrate 20 may comprise a sapphire growth substrate 20 and the carrier substrate may comprise an alumina carrier substrate 30. In another specific embodiment, the growth substrate 20 may comprise a monocrystalline silicon carbide growth substrate 20 and the carrier substrate may comprise a polycrystalline silicon carbide carrier substrate 30. The use of alumina and polycrystalline silicon carbide carrier substrates 30 may be desirable as alumina and polycrystalline silicon carbide are less expensive than sapphire and monocrystalline silicon carbide, respectively.

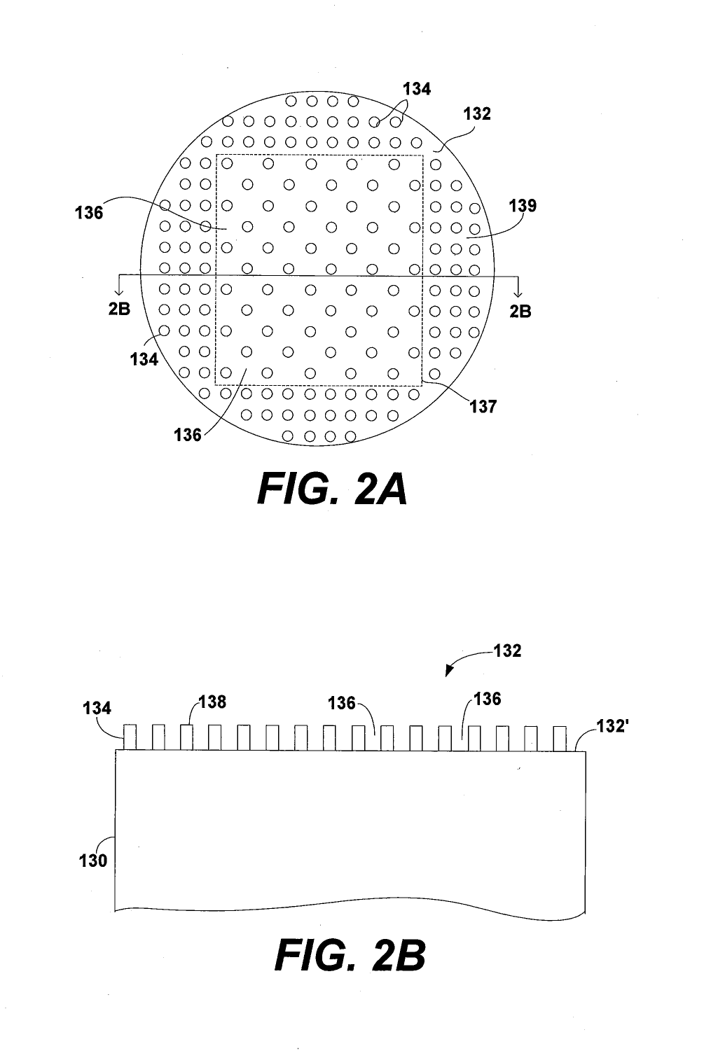

In some embodiments, the upper surface 32 of the carrier substrate 30 may be a patterned surface. The use of such a patterned surface may facilitate separating the growth substrate 20 from the carrier substrate 30 after the semiconductor growth processes are completed. While the patterned surface is not illustrated in FIGS. 1A-1D to simplify the drawings, various examples of patterned surfaces are discussed below with reference to FIGS. 2 and 4-8.

In the embodiment of FIGS. 1A-1D, the growth substrate 20 and the carrier substrate 30 have the same diameter. It will be appreciated that this may not be the case in other embodiments, In some cases, the growth substrate 20 may have a smaller diameter than the carrier substrate 30. In other embodiments, the carrier substrate 30 may have a smaller diameter than the growth substrate 20.

The bonding material 40 may comprise a separate material that is deposited and/or formed between the carrier substrate 30 and the growth substrate 20. Appropriate bonding materials 40 may be selected based on the materials of the growth substrate 20 and the carrier substrate 30. In some embodiments, the bonding material may include oxide. For example, AlO₂, SiO₂, SiO₂/Si and SiO₂/Si/SiO₂ may comprise suitable bonding materials 40. In other embodiments, silicon or carbon based glue or bonding materials 40 may be used. If the carrier substrate 30 and/or the growth substrate 20 includes oxide or has a surface which may readily be oxidized, then the native oxide material may be sufficient to bond the substrates 20, 30 together and it may not be necessary to include a separate bonding material 40. For example, the oxygen atoms in a sapphire (Al₂O₃) carrier substrate 30 will naturally bond with the oxygen atoms in a sapphire growth substrate 20.

In some embodiments, the growth substrate 20 may be bonded to the carrier substrate 30 at room temperature. Prior to bonding, the upper surface 32 of the carrier substrate and the lower surface 24 of the growth substrate may be cleaned and subjected to one or more polishing steps such as, for example, chemical mechanical polishing. The upper surface 32 of the carrier substrate and the lower surface 24 of the growth substrate 20 may be cleaved along the same crystallographic axes to enhance bonding. The bonding may be performed in a clean room environment. With many substrate materials, if the mating surfaces of the growth and carrier substrates 20, 30 are sufficiently smoothed (e.g., RMS roughness of preferably less than 1 nm), then a sufficient bond may be obtained using room temperature bonding. Typically, the strength of the bond increases if the composite substrate 10 is heat treated, as is the case when the composite substrate 10 is used as a substrate for epitaxial semiconductor growth. By way of example, room temperature bonding of two smooth sapphire substrates may result in a bonding energy of about 150 mJ/m². If the composite substrate is annealed at 1100° C., the bonding energy may increase to approximately 3000 mJ/m².

As discussed above, the upper surface 32 of the carrier substrate 30 may be patterned in some embodiments. Such patterning may provide multiple benefits. For example, by patterning the upper surface 32 of the carrier substrate 30, the amount of surface area where the carrier substrate 30 contacts (i.e., either directly or through a bonding material 40) the growth substrate 20 may be decreased, which may weaken the bond between the two substrates 20, 30. As techniques according to some embodiments of the present invention include the step of separating the growth substrate 20 from the carrier substrate 30, it may be desirable to have a relatively weak bond between the two substrates, so long as the bond is sufficiently strong to withstand the semiconductor growth environment so that the epitaxial growth process is as consistent (or nearly as consistent) as growth processes that use a single, thicker, growth substrate. Additionally, the recesses in the patterned upper surface 32 of the carrier substrate 30 may form voids at the interface between the upper surface 32 of the carrier substrate and the lower surface 24 of the growth substrate 20 when the growth substrate is bonded to the carrier substrate 30. Openings may be provided that allow liquids or gases to flow into these voids which may then be used to separate the growth substrate 20 from the carrier substrate 30 as will be discussed in greater detail below.

As shown in FIG. 1D, one or more epitaxial layers (or other crystal layers) 50 may be formed on the upper surface 22 of the growth substrate 20. For example, if the growth substrate 20 comprises a silicon carbide or sapphire growth substrate 20, the epitaxial layers 50 may comprise a plurality of gallium nitride-based and/or aluminum nitride-based semiconductor layers 50. Typically, after these semiconductor epitaxial layers 50 are grown on the growth substrate 20, the epitaxial layers 50 may be patterned and/or various metal layers and/or passivation layers (not shown) may be formed on the epitaxial layers 50 to form one or more semiconductor devices. In the case where multiple semiconductor devices are formed on the growth substrate 20, the growth substrate 20 may be diced to singulate the individual semiconductor devices.

While the use of the carrier substrates 30 according to embodiments of the present invention may be particularly advantageous when the growth substrate 20 and the epitaxial layers 50 are formed using different materials (as differences in the coefficients of thermal expansion of the different materials may lead to warping), it will be appreciated that in some embodiments the growth substrate 20 and the epitaxial layers 50 may comprise the same material. For example, in some embodiments, gallium nitride based epitaxial layers 50 may be grown on a gallium nitride growth substrate 20 that is bonded to a gallium nitride, sapphire or silicon carbide carrier substrate 30. The growth substrate 20 may, for example, have a thickness based on a desired or required thickness of the final semiconductor devices, and the carrier substrate 30 may be provided so that the overall thickness of the substrate is increased during manufacture, which may have certain advantages.

FIGS. 2A and 2B are an enlarged plan view and an enlarged cross-sectional view of a carrier substrate 130 according to embodiments of the present invention that has a patterned upper surface 132. As shown in FIGS. 2A-2B, the upper surface 132 has been patterned so that the upper surface 132 comprises a plurality of protrusions 134 and a plurality of recessed regions 136 therebetween. In the embodiment of FIGS. 2A-2B, each protrusion 134 comprises a cylindrical pillar that extends upwardly from a recessed surface 132′. In other embodiments, the protrusions 134 may comprise, for example, trapezoidal or truncated pyramidal pillars that extend upwardly from a recessed surface 132′. In embodiments where top ends of the pillars have a first surface area and bottom ends of the pillars have a second surface area, typically the top ends (i.e., the ends that connect to the growth substrate 20) may have smaller surface areas than the bottom ends. The recessed regions 136 comprise the area between the pillars 134. In the embodiment of FIGS. 2A-2B, the recessed regions 136 are connected to provide a single, continuous, recessed region. The upper surface 138 of each pillar may comprise a flat upper surface 138. The upper surfaces 138 of the pillars 134 may, in some embodiments, be the only material of the carrier substrate 130 that directly contacts a growth substrate that is mounted on the carrier substrate 130 to provide a composite substrate.

In some embodiments, the upper surfaces 138 of the pillars 134 may be at a height of between about 100 Angstroms to about 2000 Angstroms (or more) from the recessed surface 132′. In some embodiments, the spacing between adjacent pillars 134 may be between 2 microns and 100 microns. In some embodiments, the upper surfaces 138 of the pillars 134 may have a surface area of between 2 and 500 microns. In some cases, the upper surfaces 138 of the pillars 134 may be polished after the patterning process that is used to form the pillars 134 and recessed regions 136 is performed, while in other embodiments such polishing may not be necessary. The pillars 134 may be sufficiently tall such that when a growth substrate is placed on the upper surface 132 of the carrier substrate 130 the lower surface of the growth substrate will only contact the pillars 134 and will not contact the recessed surface 132′ that defines the bottom of the recessed regions 136. In some embodiments, pillars/protrusions 134 of differing heights may be provided so that the growth substrate 120 does not necessarily contact every pillar/protrusion 134. As is discussed herein, in some embodiments, the bottom surface of the growth substrate may be patterned instead of the upper surface 138 of the carrier substrate 130. In such embodiments, the bottom surface of the growth substrate may be patterned, for example, to have protrusions that are identical to the above-described protrusions 134.

A growth substrate may be bonded to the upper surfaces 138 of the pillars 134 to provide a composite substrate. As is readily apparent from FIG. 2A, the combined surface area of upper surfaces 138 of the pillars 134 may be substantially less than the surface area of the upper surface 132 of the carrier substrate 130 prior to the patterning operation (or, equivalently, the surface area of the lower surface of the carrier substrate 130 in cases where the carrier substrate is a thin disk). In some embodiments, the upper surfaces 138 of the protrusions 134 that contact the growth substrate of a composite substrate may have a total surface area that is less than 35% of the surface area of the lower surface of the carrier substrate 130. In other embodiments, the upper surfaces 138 of the protrusions 134 that contact the growth substrate of the composite substrate may have a total surface area that is less than 50% of the surface area of the lower surface of the carrier substrate 130. In still other embodiments, the upper surfaces 138 of the protrusions 134 that contact the growth substrate of the composite substrate may have a total surface area that is less than 60% of the surface area of the lower surface of the carrier substrate 130.

As is shown in FIG. 2A, the density of the protrusions 134 need not be constant across the upper surface 132 of the carrier substrate 130. For example, in some embodiments, the density of the protrusions 134 may be reduced in a central region 137 of the upper surface of the carrier substrate as compared to the density in a peripheral region 139 that surrounds the central region 137. Such an approach may facilitate later separating the growth substrate from the carrier substrate 130, since the increased open area in the central region 137 may facilitate, for example, generating a pressure differential in this region that is sufficient to break the bonds between the carrier substrate 130 and the growth substrate bonded thereto during the de-bonding operation, since the pressure differential may be maintained in the central region 137. In contrast, if the peripheral region 139, as opposed to the central region 137, had the reduced density of protrusions 134 were on one side of the upper surface 132 then it may be more difficult to maintain the pressure differential, as the greater open area along the edge of the carrier substrate 130 may allow the pressure to escape. When this occurs, the growth substrate may start to peel off the carrier substrate 130 on one side, whereas in the aforementioned method where the reduced density of protrusions are in the central region 137 it may be easier to maintain the pressure differential so that the growth substrate “pops” off the carrier substrate 130.

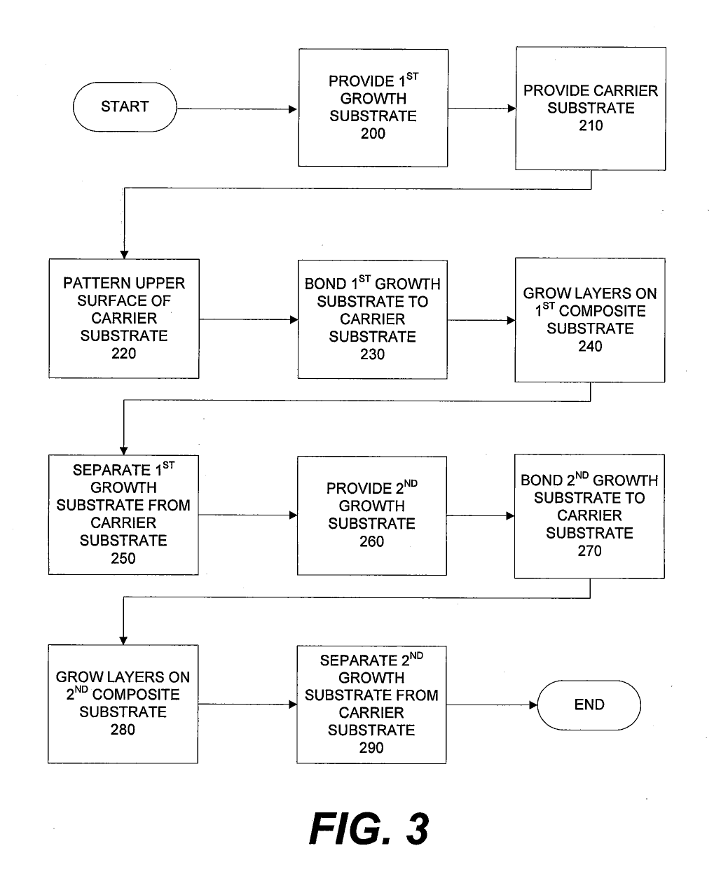

FIG. 3 is a flow chart illustrating a method of fabricating a semiconductor device according to certain embodiments of the present invention. As shown in FIG. 3, operations may begin with the provision of a growth substrate that has a thickness within a preselected range (block 200). For example, the growth substrate may have a thickness within a range that may remove any need to thin the growth substrate following semiconductor growth, or may have a thickness that is selected so that only a limited amount of thinning may be required. A carrier substrate may also be provided (block 210). The upper surface of the carrier substrate may then be patterned (block 220). In some embodiments, a photo mask may be provided on the upper surface of the carrier wafer and exposed to light to form a patterned photo mask on the upper surface of the carrier substrate. The patterned photo mask may be used as an etching mask during a dry and/or wet etching process that is used to pattern the upper surface of the carrier substrate. The upper surface of the carrier substrate may be patterned to create one or more recesses in the upper surface. At least one protrusion extends upwardly from the bottom of the recessed region(s).

A lower surface of the growth substrate is then bonded to the carrier substrate to form a composite substrate (block 230). In some embodiments, the growth substrate may be bonded directly to the carrier substrate. In such embodiments, elements of the growth substrate and the carrier substrate such as, for example, oxygen atoms, may bond together to bond the growth substrate to the carrier substrate. In other embodiments, a separate bonding material may be interposed between the growth substrate and the carrier substrate. Next, one or more semiconductor growth processes may be performed on the composite substrate at a growth temperature of at least 500° C. to form one or more semiconductor layers on an upper surface of the growth substrate (block 240). After the composite substrate is removed from the growth reactor (and either or after various post-growth processing steps are performed), the growth substrate may be separated from the carrier substrate (block 250).

After the growth substrate is separated from the carrier substrate, a second growth substrate having a thickness within a preselected range may be provided (block 260). A lower surface of the second growth substrate may then be bonded to the carrier substrate to provide a second composite substrate (block 270). At least one semiconductor growth process may then be performed on the second composite substrate to form one or more semiconductor layers on an upper surface of the second composite substrate (block 280). Then, the second growth substrate may be separated from the carrier substrate (block 290).

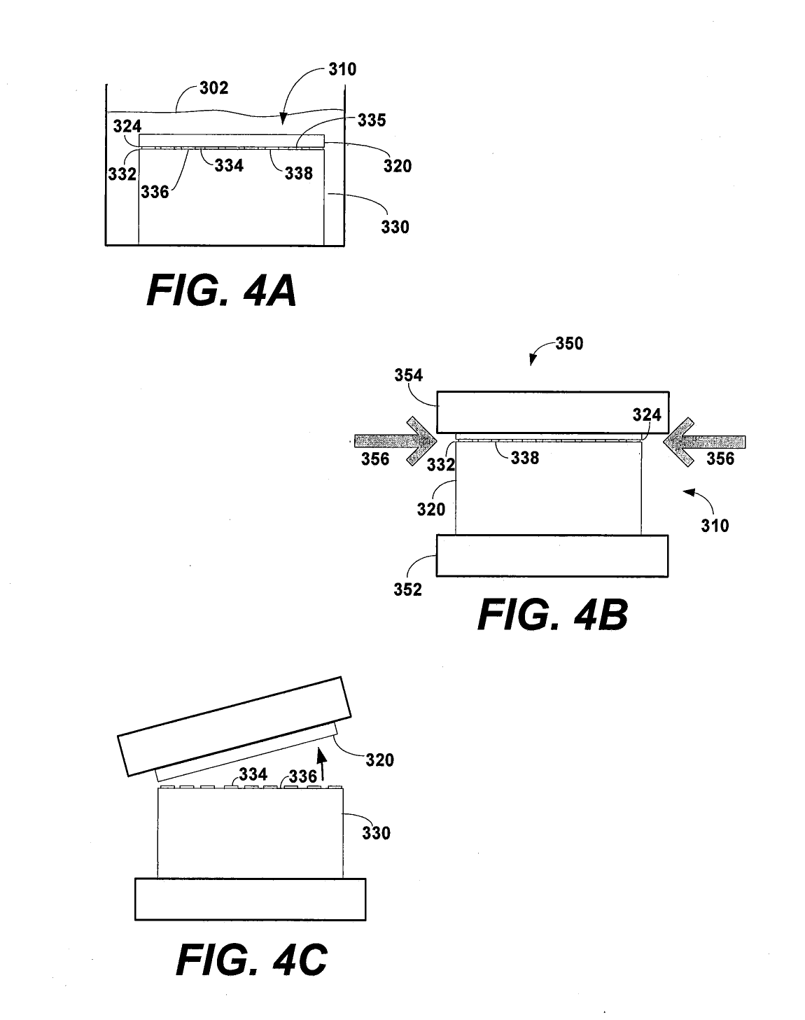

FIGS. 4A-4C are schematic side-view diagrams illustrating a method of separating a growth substrate 320 from a carrier substrate 330 according to certain embodiments of the present invention. In the embodiment of FIGS. 4A-4C, a composite substrate 310 includes the growth substrate 320 and the carrier substrate 330. Water 302 is deposited in voids 338 that are provided at the interface between the growth substrate 320 and the carrier substrate 330 as a result of recesses 336 that are patterned into the upper surface 332 of the carrier substrate 330. The composite substrate 310 is then rapidly heated to convert the water 302 to steam to create a pressure differential in the voids 338 provided at the interface between the carrier substrate 330 and the growth substrate 320. This pressure differential may be sufficient to break the bonds between the two substrates 320, 330 thereby separating the growth substrate 320 from the carrier substrate 330.

Referring first to FIG. 4A, the composite substrate 310 may be immersed in a water bath 302 in order to allow water 302 to enter into the voids 338 that are provided at the interface between the upper surface 332 of the carrier substrate 330 and the lower surface 324 of the growth substrate 320. In the depicted embodiment, the upper surface 332 of the carrier substrate has a plurality of protrusions 334 that define one or more recesses 336 therebetween. These recesses create the voids 338. The water 302 may fill these voids 338. While in FIG. 4A this is accomplished by submerging the composite, substrate 310 in water 302, it will be appreciated that any appropriate technique may be used. For example, in other embodiments, water 302 may be injected into the voids 338 between the upper surface 332 of the carrier substrate 330 and the lower surface 324 of the growth substrate 320 through openings 335 that provide access to the voids 338.

Referring to FIG. 4B, the composite substrate 310 next may be placed in a fixture 350. The fixture 350 may include a hot plate 352. The lower surface of the carrier substrate 330 may directly contact the hot plate 352. The fixture 350 may further include a pad 354 that is placed on the upper surface of the growth substrate 320. The hot plate 352 may be used to rapidly heat the composite substrate 310 in order to convert the water 302 that is deposited between the upper surface 332 of the carrier substrate 330 and the lower surface 324 of the growth substrate 320 into steam. If the openings 335 that provide access to the voids 338 are sufficiently small, the water 302 may be converted to steam before much water/steam can escape through the openings 335, and hence a significant pressure differential may be formed between the two substrates 320, 330 as the water 302 expands as it turns into steam. As is also shown by the arrows 356 in FIG. 4B, pressure may be applied at the interface between the growth substrate 320 and the carrier substrate 330 (e.g., steam jets) to reduce the amount of steam that can escape. As shown in FIG. 4C, this increase in pressure may be sufficient to separate the growth substrate 320 from the carrier substrate 330.

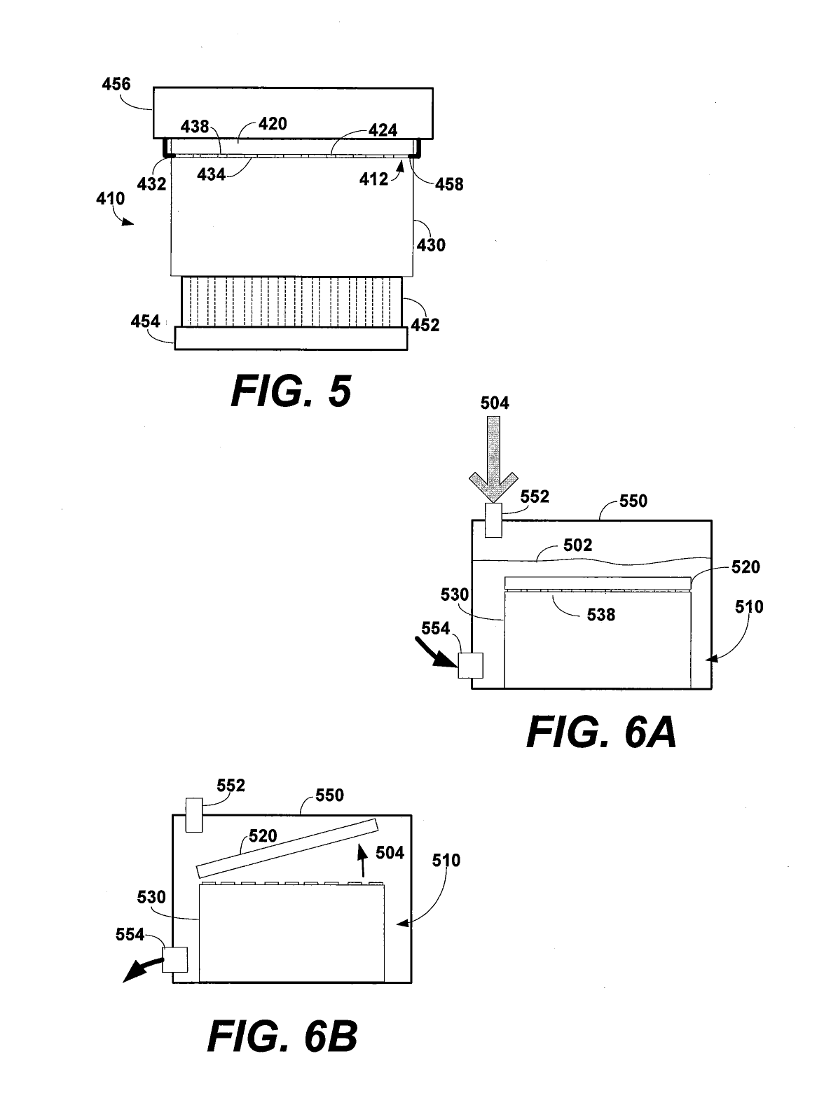

FIGS. 4A-4C illustrate one example technique that may be used to separate the growth substrate from the carrier substrate after the semiconductor growth processes have been completed. It will be appreciated, however, that numerous different techniques may be used. FIG. 5 is a schematic diagram illustrating another method of separating a growth substrate from a carrier substrate according to further embodiments of the present invention in which the carrier and growth substrates are separated from each other by pulling on one or both of the substrates.

As shown in FIG. 5, a composite substrate 410 is formed that includes a growth substrate 420 and a carrier substrate 430. The lower surface of the carrier substrate 430 is placed on a perforated plate 452 having a vacuum 454 attached to the lower surface thereof. A fixture 456 is used to hold the growth substrate 420 in place. The upper surface 432 of the carrier substrate 430 may be patterned to have a plurality of upwardly extending protrusions 434. The protrusions 434 formed therein are offset from the outer perimeter of the carrier substrate 430. As a result, the composite substrate 410 may have a circular groove 412 at the location where the carrier substrate 430 is joined to the growth substrate 420. The fixture 456 may include a lip 458 that may be inserted in this groove 412. Once the growth substrate 420 is captured by the fixture 456, the vacuum 454 may be turned on to hold the carrier substrate 430 firmly against the perforated plate 452, and the fixture 456 may then be moved away from the perforated plate 452 and vacuum 454 (either by moving the fixture 456, the plate/vacuum 454 or both). As the carrier substrate 430 and growth substrate 420 are pulled apart in this fashion, the bonds between the upper surfaces 438 of the protrusions 434 and the lower surface 424 of the growth substrate 420 may be broken so that the growth substrate 420 is separated from the carrier substrate 430.

FIG. 6 is a schematic diagram illustrating a method of separating a growth substrate from a carrier substrate according to still further embodiments of the present invention in which a pressurized liquid 502 is deposited between a carrier substrate 530 and a growth substrate 520 that are joined together to form a composite substrate 510. In some embodiments, the pressurized liquid may be carbon dioxide 502 that is sufficiently pressurized to be in a liquid form. The composite substrate 510 may be placed in a vessel 550. Carbon dioxide gas 504 may be pumped into the vessel 550 via a first input 552 and the vessel 550 may be pressurized via a second input 554. The vessel 550 may be sufficiently pressurized such that the carbon dioxide gas 504 transforms state into liquid carbon dioxide 502. The composite substrate 510 may be immersed in the liquid carbon dioxide 502 in order to allow the liquid carbon dioxide 502 to flow into the voids 538 in the upper surface of the carrier substrate 530. As shown in FIG. 613, the vessel 550 may then be rapidly depressurized so that the liquid carbon dioxide 502 is converted to carbon dioxide gas 504. As the carbon dioxide transforms from a liquid state to a gaseous state, it expands and this expansion may create a pressure differential between the upper surface of the carrier substrate 530 and the lower surface of the growth substrate 520 that may be sufficient to separate the growth substrate 520 from the carrier substrate 530.

One potential advantage of using liquid carbon dioxide as the fluid that is flowed into the voids is that liquid carbon dioxide may exhibit substantially less surface tension as compared to water. As the openings into the voids may be small, surface tension of the water molecules may make it difficult to fill the voids with water. As liquid carbon dioxide exhibits substantially less surface tension, smaller openings and/or voids may be used and it may still be possible to substantially fill the voids with the liquid carbon dioxide.

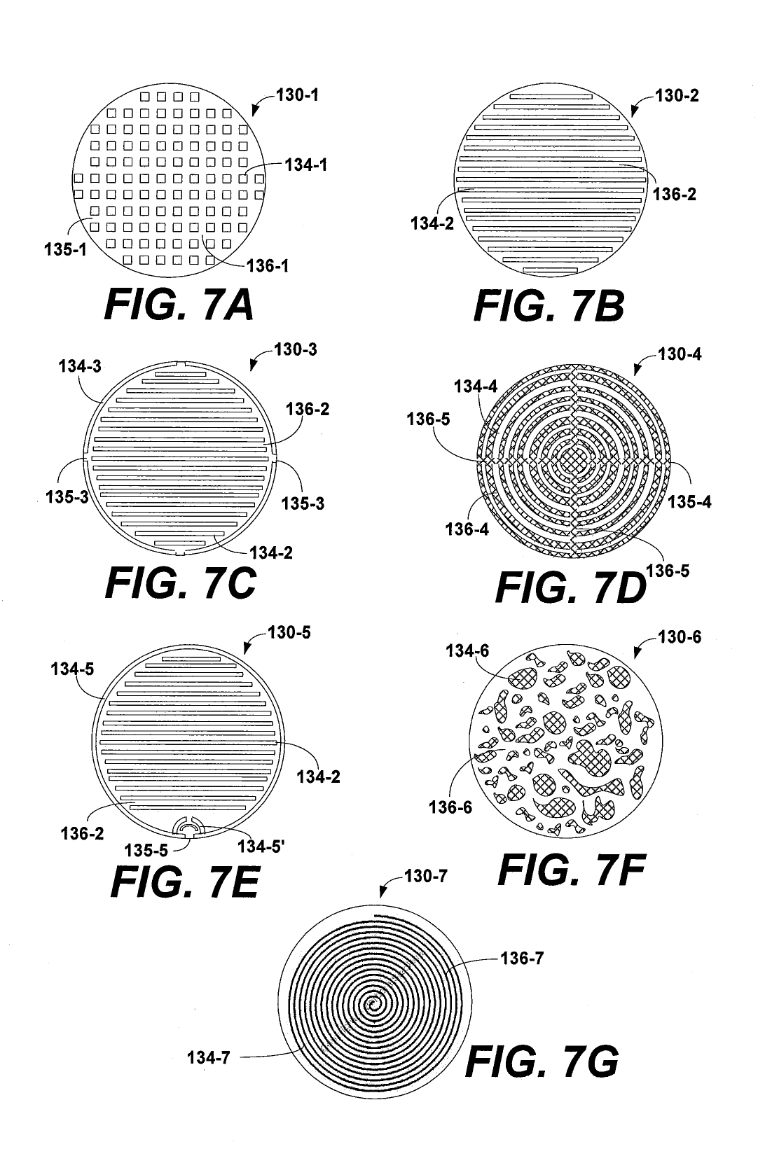

As discussed above, in some embodiments of the present invention, the upper surface of a carrier substrate (e.g., carrier substrate 130) may be patterned to form one or more recesses 136 that define one or more upwardly extending protrusions 134. A wide variety of different patterns may be used. FIGS. 2A-2B illustrate one example pattern. FIGS. 7A-7G are schematic plan views of patterned carrier substrates according to embodiments of the present invention that have different example patterns.

FIG. 7A illustrates a carrier substrate 130-1 where the protrusions 134 comprise a plurality of upwardly extending square columns 134-1. Recesses 136-1 are defined between the protrusions 134-1. The recesses 136-1 form a continuous recessed region. Openings 135-1 provide access to the recesses 136-1 when a growth substrate is placed on the carrier substrate 130-1 to cover the upper surface of the carrier substrate 130-1. In the embodiment of FIG. 7A (unlike the embodiment of FIGS. 2A-2B, the density of the protrusions is relatively constant across the upper surface of the carrier substrate 130-1 (although the density varies somewhat along the periphery of the substrate).

FIG. 7B illustrates a carrier substrate 130-2 that has protrusions 134 in the form of a plurality of upwardly extending horizontal bars 134-2. Recesses 136-2 are provided between adjacent ones of the bars 134-2. As the bars 134-2 do not extend all the way to the peripheral edge of the upper surface, the recesses 136-2 form a continuous recessed region.

FIG. 7C illustrates a carrier substrate 130-3 that is very similar to carrier substrate 130-2 in that it also has protrusions 134 in the form of a plurality of upwardly extending horizontal bars 134-2 and recesses 136-2 are provided between adjacent ones of the bars 134-2. Additionally, carrier substrate 130-3 further includes four curved protrusions 134-3 that are provided at the periphery of the upper surface of the substrate 130-3. Each protrusion 134-3 extends approximately 85 degrees along the periphery, and is separated on each side from adjacent ones of the protrusions 134-2 by a gap of about 5 degrees. These gaps define openings 135-3 that may allow a fluid to be injected or otherwise flow into and fill the recesses 136-2 when a growth substrate is deposited on upper of the carrier substrate 130-3.

As discussed above, in some embodiments a growth substrate may be separated from a carrier substrate by flowing a fluid into voids that are provided at the junction of a lower surface of a growth substrate and the upper surface of a carrier substrate due to a pattern formed in the upper surface of the carrier substrate that includes one or more recesses. The fluid in the voids may be caused to change from a liquid state to a gaseous state by modifying the temperature and/or pressure conditions. As the fluid expands during this state change, it generates pressure that is used to separate the growth substrate from the carrier substrate. The increased pressure will tend to force the fluid out of the recesses through the openings 135-3, and this escaping volume of material in turn decreases the pressure. Thus, if the openings are too big and/or to numerous, it may be more difficult to generate a sufficient pressure differential. The embodiment of FIG. 7C provides only a few small openings 135-3 into the recesses 136-2, and hence will not allow much fluid to escape as the fluid changes state, thereby generating a larger pressure differential. In contrast, the substrate 130-1 includes far more openings 135-1.

FIG. 7D illustrates a carrier substrate 130-4 where the protrusions 134 comprise a plurality of upwardly extending concentric circles 134-4. A plurality of recesses 136-4 in the form of concentric circles are provided between the protrusions 134-4. Four bar-shaped recesses 136-5 are also provided that bisect the protrusions 134-4 at spacings that are ninety degrees apart. outer ends of the bar-shaped recesses form the openings 135-4 into the recessed region.

FIG. 7E illustrates a carrier substrate 130-5 where the protrusions 134 comprise a plurality of upwardly extending horizontal bars 134-2 as in the embodiments of FIGS. 7B and 7C and a nearly circular protrusion 134-5 that extends almost completely around the periphery of the upper surface of the substrate 130-5. Recesses 136-2 are provided between adjacent ones of the bars 134-2. The nearly circular protrusion 134-5 has a gap region that defines an opening 135-5 that may allow a fluid to be injected or otherwise flow into and fill the recesses 136-2 when a growth substrate is deposited on upper of the carrier substrate 130-5. Additionally, a plurality of curved protrusions 134-5′ are provided adjacent the opening 135-5. The provision of only a single opening 135-5 into the recesses 136-2 and the provision of the protrusions 134-5′ may inhibit the outward flow of a fluid that is deposited in the recesses 136-2, which may make it easier to generate sufficient pressure in the recesses 136-2 that a growth substrate may be separated from the carrier substrate in the various example ways that are discussed herein.

FIG. 7F illustrates a carrier substrate 130-6 that has protrusions 134 in the form of a plurality of upwardly extending randomly shaped patterns 134-6. Recesses 136-6 are provided between adjacent ones of the patterns 134-6.

FIG. 7G illustrates a carrier substrate 130-7 that has a single protrusion 134 in the form of a continuous upwardly extending spiral 134-7. A continuous spiral shaped recesses 136-7 is defined by the spiral protrusion 134-7.

In each of the above examples, the upper surface of the carrier substrate is patterned so that one or more recesses are provided therein. The recesses may extend into the center of the upper surface of the carrier substrate. When a growth substrate is bonded to the upper surface of the carrier substrate to form a composite substrate, these recesses become voids 138. Openings 135 may be provided along the periphery of the interface between the carrier substrate and the growth substrate. The openings 135 may be in fluid communication with the voids 138 and may be used, for example, to allow a fluid to flow into the voids 138 so as to fill the voids 138. Once the voids 138 are filled, the pressure may be changed so that the fluid expands (e.g., by converting from a liquid to a gas). As the fluid expands, a pressure differential may be created between the carrier substrate and the growth substrate that is sufficient to break the bonds therebetween so that the growth substrate is separated from the carrier substrate.

With some materials, there is a possibility that the patterning of the upper surface of the carrier substrate may negatively affect the epitaxial growth of semiconductor layers on the upper surface of the growth substrate. For example, the voids at the interface between the carrier substrate and the growth substrate may impact the temperature at the upper surface of the growth substrate, particularly if the growth substrate is relatively thin. If such temperature differentials exist, it may affect epitaxial growth in a variety of ways, as is known to those of skill in the art. As one example, in the growth of gallium nitride-based light emitting diodes, such temperature differentials can affect the percentage of indium and aluminum that are included in various gallium nitride-based layers of the device, so that these layers may have slightly differing amounts of indium and/or aluminum as a function of location on the substrate. This can impact, for example, the wavelength of the light emitting diodes that are formed from the substrate. In some embodiments, a large number of protrusions may be provided with small recesses between the protrusions, as such a design may help reduce temperature differentials at the upper surface of the growth substrate.

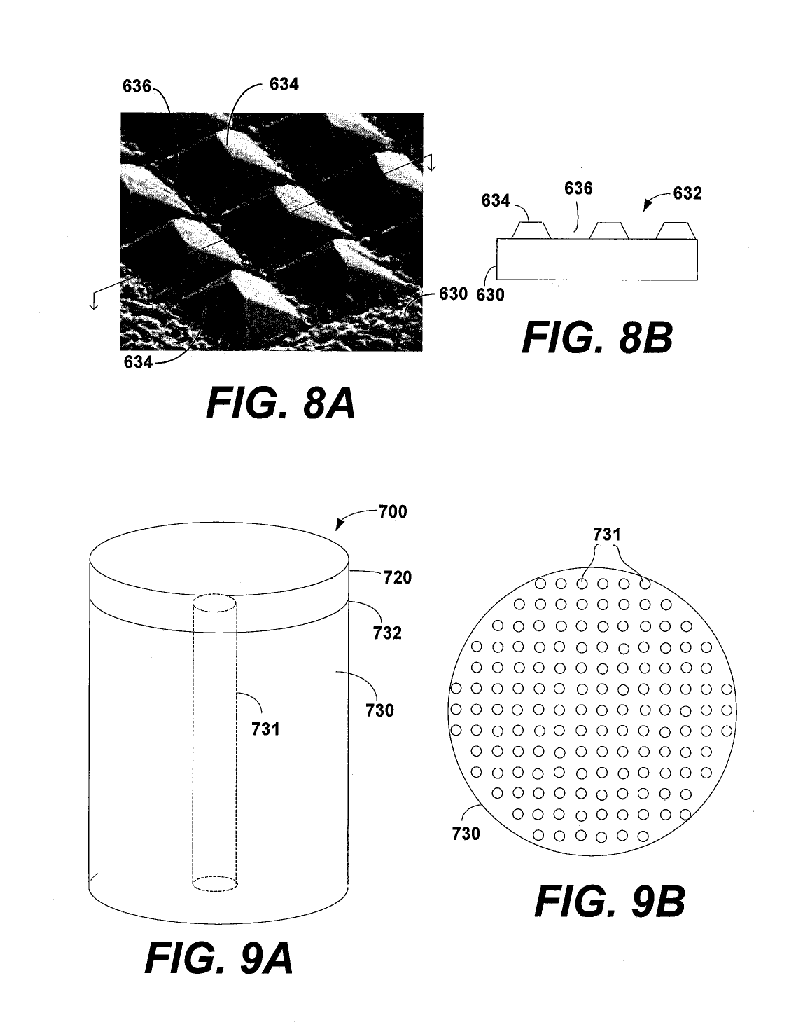

As discussed above, in some embodiments, the upper surface of the carrier substrate may be patterned using, for example, photolithography and etching processes or other substrate patterning processes known to those of skill in the art. In further embodiments, of the present invention, the upper surface of the carrier substrate may instead (or additionally) be intentionally roughened so that voids will be present when the growth substrate is bonded to the upper surface of the carrier substrate. For example, as shown in FIG. 8A, the upper surface of a carrier substrate 630 may include a plurality of protrusions 634 in the form of pyramidal or truncated pyramidal protrusions 634 or other structures. Recesses 636 may be defined between the protrusions. The protrusions 634 may result, for example, from a sawing operation that is used to cut the carrier substrate 630 from, for example, a boule.

Referring to FIG. 8B, a chemical mechanical polishing (“CMP”) process may be performed on the upper surface 632 of the carrier substrate 630 in order to reduce the height of the protrusions 634 to a desired height. This CMP process may be omitted in some embodiments.

In some embodiments, the lower surface of the growth substrate and/or the upper surface of the carrier substrate may be polished via CMP and/or other suitable polishing techniques. By polishing one or both of these surfaces, improved bonding may be achieved between the carrier substrate and the growth substrate. The bonding strength of such polished surfaces may also be more predictable. While it may be difficult with some materials to separate a growth substrate from a carrier substrate if the mating surfaces are polished surfaces, this potential problem can be avoided, as discussed above, by patterning one or both surfaces so that only a pre-selected percentage of the surface area of the bottom of the growth substrate contacts (and hence bonds to) the upper surface of the carrier substrate. This percentage can be selected in advance so that (1) the composite substrate comprising a growth substrate bonded to a carrier substrate will be stable and appear as a single substrate during the semiconductor growth processes and (2) the growth substrate can readily be separated from the carrier substrate after removal from the growth reactor without damaging the growth substrate, the semiconductor layers grown on the growth substrate or the carrier substrate. Since the polished surfaces may provide a predictable bond strength, the polishing step may allow the growth substrate to be bonded to the carrier substrate with strength within a desirable range that meets the above criteria, as the percentage of the surface area of the bottom of the growth substrate that is bonded to the carrier substrate may be selected so that the bond strength falls within a desired range.

In some embodiments, the percentage of the surface area of the lower surface of the growth substrate that is bonded to the carrier substrate may be less than 60%. In other embodiments, the percentage may be less than 50%. In still other embodiments, the percentage may be less than 35%. In some embodiments, the percentage may even be less than 25%. As discussed above, in some embodiments a smaller percentage of the central region of the lower surface of the growth substrate may be bonded to the carrier substrate than the percentage of the peripheral region of the lower surface of the growth substrate (i.e., the size and/or number of voids in the central region is greater than in the peripheral region). Having increased voids in the central region may make it easier to generate a pressure differential between the growth substrate and the carrier substrate that is used to cleanly separate the growth substrate from the carrier substrate.

Pursuant to still further embodiments of the present invention, the carrier substrate may include one or more perforations. For example, as shown in FIG. 9A, in one embodiment, a carrier substrate 730 may be provided that includes a single perforation 731 that extends from a lower surface 733 to a upper surface 732 thereof. In the depicted embodiment, the perforation 731 extends longitudinally through the center of the carrier substrate 730. The perforation 731 may have a circular cross-section, although any shaped cross-section may be used. The perforation 731 may make it easier to generate a pressure differential between the carrier substrate 730 and a growth substrate 720 that allows easy separation of the growth substrate 720 from the carrier substrate 730. By way of example, a nozzle may be sized to fit within the perforation and may be used to inject a pressurized liquid or a gas into the perforation 731. The pressurized liquid or gas may apply an upward force on the lower surface of the growth substrate 720 that may be used to break the bonds between the carrier substrate 730 and the growth substrate 720. While the carrier substrate 730 depicted in FIG. 9A includes a single perforation 731, it will be appreciated that more than one perforation 731 may be provided. For example, FIG. 9B is a plan view of the lower surface of a modified version of carrier substrate 730 that includes dozens of longitudinally extending perforations 731 that extend all the way through the carrier substrate 730. In some embodiments, hundreds or even thousands of perforations 731 could be provided through the carrier substrate 730. The perforations 731 may be created, for example, simply by drilling holes in the carrier substrate 730. As the carrier substrate 730 may be reused many times, the extra cost associated with creating the perforations 731 may be acceptable since it can be spread over many growth substrates 720.

In some embodiments, the perforations 731 may provide paths that allow etchants to be deposited at the locations where the upper surface of the carrier substrate 730 bonds to the lower surface of the growth substrate 720. These etchants may be used to remove some of the material that bonds the growth substrate to the carrier substrate. The use of etchants may be particularly useful when the growth substrate and the carrier substrate comprise different materials, as the etchants may, for example, remove some of the lower surface of the growth substrate without significantly etching the carrier substrate. In this manner, the etchants may be used to separate the two substrates without significantly damaging the upper surface of the carrier substrate so that the carrier substrate may be reused.

In still other embodiments, suction may be applied to the lower of the carrier substrate to facilitate drawing etchants into the voids through, for example, the openings 135 that are discussed above.

Moreover, as noted above, surface tension of the fluid may limit how small the openings may be that provide access to the voids and/or the size of the voids, as the surface tension of the fluid may make it more difficult to fill the voids with fluid. If one or more perforations are provided in the carrier substrate, a vacuum may be used to draw the fluid into the voids through the openings.

Example methods of separating the growth substrate from the carrier substrate have been described above. These methods include various methods that generate a pressure differential at the interface of the growth substrate and the carrier substrate and methods that etch the areas where the growth substrate bonds to the carrier substrate. It may be particularly effective if the pressure differential may be generated near the middle of the upper surface of the carrier substrate as this may be more effective at breaking the bonds between the carrier substrate and the growth substrate as compared to pressure that is generated closer to or at the periphery of the upper surface of the carrier substrate. It will also be appreciated that any appropriate method of separating the growth substrate from the carrier substrate may be used. For example, in further embodiments, spalling techniques as described, for example, in U.S. Patent Publication No. 2010/0310775 may be used to more readily separate a growth substrate from a carrier substrate. In still other embodiments, ultraviolet lasers may be used to decompose the material at the interface where the growth wafer bonds to the carrier wafer to separate the growth wafer from the carrier wafer.

FIG. 10 illustrates another method of fabricating a semiconductor device according to certain embodiments of the present invention. As shown in FIG. 10, operations may begin with a growth substrate being provided and a CMP process being performed on the lower surface of this growth substrate (block 800). A carrier substrate is likewise provided, and an upper surface of the carrier substrate may also be subjected to a CMP process (block 810), As discussed above, by polishing these surfaces, a better and more consistent bond may be obtained between the upper surface of the carrier substrate and the lower surface of the growth substrate. Next, in some embodiments, a bonding material may be deposited (including deposited by a growth process) on the upper surface of the carrier substrate and/or on the lower surface of the growth substrate (block 820). The bonding material may comprise, for example, AlO₂, SiO₂, SiO₂/Si and SiO₂/Si/SiO₂. It will also be appreciated that the bonding material may be omitted in some cases, such as, for example, when the carrier and growth substrates include native oxides or other materials that will form a sufficiently strong bond when the growth substrate is placed on the carrier substrate. Next, a photoresist may be formed on the upper surface of the carrier substrate, and may be exposed to light to form a photoresist pattern (block 830). This photoresist pattern may then be used to pattern the upper surface of the carrier substrate via, for example, wet and/or dry etching (block 840). Once the patterning process is completed, the photoresist may be stripped from the carrier substrate (block 850). A second CMP process may also be performed on the carrier substrate, if desired (block 860). Then, the lower surface of the growth substrate may be mated with the upper surface of the carrier substrate to bond the two substrates together to provide a composite substrate (block 870). This bonding step may be performed, for example, at room temperature. The composite substrate may then be placed in a semiconductor growth chamber and one or more crystal layers (e.g., epitaxially grown semiconductor layers) may be grown on the upper surface of the composite substrate (block 880). Once the growth processes are completed, the composite substrate may be removed from the growth chamber, and the growth substrate may be separated from the carrier substrate using, for example, any of the above-described separation techniques (block 890). If a separate bonding material was used to bond the growth substrate to the carrier substrate, the remaining bonding material may be removed from the carrier substrate by, for example, an etching or stripping process (block 895).

In some embodiments, the upper surface of the carrier substrate may be implanted with ions prior to the bonding operation. For example, hydrogen ions may be implanted into the upper surface of the carrier substrate. The implantation of ions may be used to embrittle the upper surface of the carrier substrate, which may make it easier to cleanly separate the growth substrate from the carrier substrate.

As discussed above, in some embodiments, the upper surface of the carrier substrate may be patterned in order to create recesses. When the growth substrate is placed on top of the carrier substrate, these recesses become voids that may receive a fluid that is used to create a pressure differential to separate the growth substrate from the carrier substrate. It will be appreciated, however, that in further embodiments of the present invention, the lower surface of the growth substrate may be patterned instead of, or in addition to, the upper surface of the carrier substrate to create such voids.

For example, FIG. 11 is a side view of a composite substrate 910 according to further embodiments of the present invention that includes a growth substrate 920 and a carrier substrate 930. The growth substrate 920 has an upper surface 922 and a lower surface 924. A plurality of epitaxial layers 950 have been formed (e.g., by semiconductor growth techniques) on the top surface 922 of the growth substrate 920. The lower surface 924 is a patterned surface that includes a plurality of downwardly extending protrusions 926 that define a plurality of recesses 928 therebetween. The patterned lower surface 924 of the growth substrate 920 may facilitate separating the growth substrate 920 from the carrier substrate 930 after the semiconductor growth processes are completed.

The carrier substrate 930 has an upper surface 932 that may be bonded to the lower surface 924 of the growth substrate 920. The lower surface 924 of the growth substrate 920 may be bonded directly to the upper surface 932 of the carrier substrate 930, or intervening material(s) such as a bonding material may be interposed between the growth substrate 920 and the carrier substrate 930. In the depicted embodiment, no bonding material is used, and the growth substrate 920 is in the process of being separated from the carrier substrate 930.

In some embodiments, the protrusions 926 extending downwardly from the lower surface 924 of the growth substrate 920 may comprise light extraction structures. As known to those of skill in the art, certain geometric shapes may be patterned into light emitting surfaces of a light emitting diode (LED) in order to enhance the amount of light that is generated by the LED through the surface. In, for example, applications where LEDs are mounted in a so-called “flip-chip” arrangement where the light emitting layers of the LED are sandwiched between a mounting substrate and the growth substrate so that light is emitted through the growth substrate, the bottom surface of the growth substrate may be patterned to include such light extraction structures. Pursuant to embodiments of the present invention, the bottom surface 924 of a growth substrate 920 may be patterned both for purposes of enhancing light extraction from LED chips that are ultimately singulated from the growth substrate 920 and for purposes of facilitating separation of the growth substrate 920 from a carrier substrate 930 in order to allow, for example, the use of thinner growth substrates.

As either the upper surface of the carrier substrate or the lower surface of the growth substrate (or both) may be patterned, the composite substrates according to embodiments of the present invention may be viewed as having (1) a first substrate that has a first major surface that is patterned to include protrusions that extend away from the first major surface and a second major surface that is opposite the first major surface and (2) a second substrate that has opposed first and second major surfaces. The second major surface of the second substrate is mated with the first major surface of the first substrate. The semiconductor epitaxial layers may be formed on (1) the second major surface of the first substrate (when the growth substrate includes a patterned lower surface) or the first major surface of the second substrate (when the carrier substrate includes a patterned upper surface). Distal ends of the protrusions are joined to the second major surface of the second substrate.

As discussed above, the methods and substrates according to embodiments of the present invention may provide a number of advantages. First, the growth substrates that are used may be substantially thinner than conventional growth substrates for the same applications, as the problems caused by the potential for the substrate to warp during cool-down from crystal growth may be reduced by the provision of a relatively thick carrier substrate. The use of thinner growth substrates may result in significantly reduced material costs, and may also reduce or eliminate the need for costly back-end grinding operations that are conventionally used to reduce the thickness of the growth substrate to a desired thickness for the application at issue. Second, the provision of the thick carrier substrate may allow for even less substrate warping than is experienced in conventional processes, as the techniques according to embodiments of the present invention may remove the tradeoff between warping and substrate thickness. Accordingly, it is expected that the techniques according to embodiments of the present invention may result in improved consistency in crystal growth and in improved production yields. Third, in some cases, the growth substrate may be cut to a desired thickness so that no back-end grinding operations are required at all.

Embodiments of the present invention have been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

A variety of different example embodiments have been described above. It will be appreciated that features of the different embodiments can be combined in different ways and/or combinations to provide additional embodiments.

Certain of the embodiments of the present invention are described above with reference to flowchart illustrations. It will be understood that the operations described in various of the blocks of these flowcharts may be carried out simultaneously as opposed to sequentially and that various of the operations may be performed in a different order than shown in the example flowchart illustrations.

1. A method of fabricating a semiconductor device, the method comprising:
providing a growth substrate;
bonding a lower surface of the growth substrate to an upper surface of the carrier substrate to form a composite substrate;
performing a semiconductor growth process at a growth temperature of at least 500° C. to form a semiconductor layer on an upper surface of the growth substrate that is opposite the lower surface of the growth substrate; and
separating the growth substrate from the carrier substrate.

2. (canceled)

3. The method of claim 1, wherein the growth substrate is a first growth substrate, the composite substrate is a first composite substrate, the semiconductor layer is a first semiconductor layer and the semiconductor growth process is a first semiconductor growth process, the method further comprising the following steps:
providing a second growth substrate having a thickness within a preselected range;
bonding a lower surface of the second growth substrate to the upper surface of the carrier substrate after the first growth substrate has been separated from the carrier substrate to provide a second composite substrate; and
performing a second semiconductor growth process on the second composite substrate at a temperature of at least 500° C. to form a second semiconductor layer on an upper surface of the second growth substrate.

4. (canceled)

5. The method of claim 1, further comprising patterning the upper surface of the carrier substrate prior to bonding the lower surface of the growth substrate to the carrier substrate.

6. The method of claim 5, wherein the upper surface of the carrier substrate is patterned to form a recessed upper surface, a plurality of protrusions that extend upwardly from the recessed upper surface, and a plurality of recessed regions that are in between the protrusions.

7. The method of claim 6, wherein upper surfaces of the protrusions define a bonding surface that contacts the lower surface of the growth substrate when the lower surface of the growth substrate is bonded to the upper surface of the carrier substrate, wherein the bonding surface has a surface area that is less than 50% of the surface area of the lower surface of the growth substrate.

8. (canceled)

9. The method of claim 6, wherein upper surfaces of the protrusions define a bonding surface that contacts the lower surface of the growth substrate and wherein the recessed regions define a non-contact region where the carrier substrate does not contact the lower surface of the growth substrate, and wherein in a central region of the upper surface of the carrier substrate the ratio of the surface area of the bonding surface to the surface area of the non-contact region is less than the ratio of the surface area of the bonding surface to the surface area of the non-contact region in a peripheral region of the upper surface of the carrier substrate that surrounds the central region.

10. (canceled)

11. The method of claim 1, further comprising dicing the growth substrate after separating the growth substrate from the carrier substrate without first thinning the growth substrate.

12. The method of claim 3, wherein the first growth substrate comprises a first silicon carbide growth substrate and the carrier substrate comprises a silicon carbide carrier substrate.

13. The method of claim 12, wherein the first silicon carbide growth substrate is bonded to the upper surface of the silicon carbide carrier substrate using at least one of carbon, silicon oxide, and/or silicon.

14. The method of claim 3, wherein the first growth substrate comprises a first sapphire growth substrate and the carrier substrate comprises a sapphire carrier substrate.

15. The method of claim 3, wherein the first growth substrate comprises a first sapphire growth substrate and the carrier substrate comprises an alumina carrier substrate.

16. (canceled)

17. The method of claim 1, wherein the semiconductor growth process comprises an epitaxial growth process, and wherein an epitaxial layer that is grown by the epitaxial growth process has a different coefficient of thermal expansion than does the growth substrate.

18. A method of fabricating a semiconductor device, the method comprising:
epitaxially growing a plurality of semiconductor layers on a composite substrate that includes a growth substrate having a lower surface that is bonded to an upper surface of a carrier substrate, wherein the upper surface of the carrier substrate includes recesses therein that define voids at the interface between the carrier substrate and the growth substrate;
separating the growth substrate from the carrier substrate by filling the voids with a fluid and then expanding the fluid by a hydraulic force and/or by a phase change to generate a force that separates the growth substrate from the carrier substrate.

19. The method of claim 18, wherein expanding the fluid by a hydraulic force and/or by a phase change to generate the force that separates the growth substrate from the carrier substrate comprises changing a pressure to expand the fluid to generate a force that separates the growth substrate from the carrier substrate.

20. The method of claim 18, wherein expanding the fluid by a hydraulic force and/or by a phase change to generate the force that separates the growth substrate from the carrier substrate comprises changing a temperature to expand the fluid to generate a force that separates the growth substrate from the carrier substrate.

21. (canceled)

22. The method of claim 18, wherein the fluid comprises water that is converted to steam.

23. The method of claim 18, wherein the fluid comprises a fluid that is inserted into the voids as a pressurized liquid and a reduction in the ambient pressure allows the pressurized liquid to pass through a phase change converting the liquid in the voids into a gas.

24-32. (canceled)

33. A method of fabricating a semiconductor device, the method comprising:
separating a first growth substrate which has at least one epitaxial grown semiconductor layer thereon from a carrier substrate;
bonding a lower surface of a second growth substrate to an upper surface of the carrier substrate to form a composite substrate;
performing a semiconductor growth process to form a semiconductor layer on an upper surface of the second growth substrate that is opposite the lower surface of the second growth substrate.

34. The method of claim 33, wherein the semiconductor growth process is performed at a growth temperature of at least 500° C.

35. (canceled)

36. The method of claim 33, wherein the upper surface of the carrier substrate comprises a patterned surface that has a plurality of upwardly extending protrusions, and wherein upper surfaces of the protrusions define a bonding surface that contacts the lower surface of the second growth substrate when the lower surface of the second growth substrate is bonded to the upper surface of the carrier substrate.

37. A method of fabricating a semiconductor device, the method comprising:
providing a growth substrate;
bonding a lower surface of the growth substrate to an upper surface of the carrier substrate to form a composite substrate;
performing a metal organic chemical vapor deposition growth process to form an epitaxially grown semiconductor layer on an upper surface of the growth substrate that is opposite the lower surface of the growth substrate; and
separating the growth substrate from the carrier substrate.

38. The method of claim 37, wherein the growth substrate is a first growth substrate, the composite substrate is a first composite substrate, the semiconductor layer is a first semiconductor layer and the metal organic chemical vapor deposition growth process is a first metal organic chemical vapor deposition growth process, the method further comprising the following steps:
providing a second growth substrate having a thickness within a preselected range;
bonding a lower surface of the second growth substrate to the upper surface of the carrier substrate after the first growth substrate has been separated from the carrier substrate to provide a second composite substrate; and
performing a second organic chemical vapor deposition growth process on the second composite substrate to form an epitaxially grown second semiconductor layer on an upper surface of the second growth substrate.

39. The method of claim 37, further comprising patterning the upper surface of the carrier substrate to form a recessed upper surface, a plurality of protrusions that extend upwardly from the recessed upper surface, and a plurality of recessed regions that are in between the protrusions prior to bonding the lower surface of the growth substrate to the carrier substrate.

40-47. (canceled)
